(19) United States
(12) Patent Application Publication
(10) Pub. No.: US 2015/0189746 A1
(43) Pub. Date: Jul. 2, 2015

(54) PREPREG AND USES OF THE SAME

(71) Applicant: TAIWAN UNION TECHNOLOGY CORPORATION, Chupei City (TW)

(72) Inventors: Chih-Wei Liao, Chupei City (TW); Hsien-Te Chen, Chupei City (TW); Te-Liang Yu, Chupei City (TW); Cheng-Ping Liu, Chupei City (TW)

(21) Appl. No.: 14/583,232

(22) Filed: Dec. 26, 2014

Related U.S. Application Data
(60) Provisional application No. 61/921,113, filed on Dec. 27, 2013.

(30) Foreign Application Priority Data
Dec. 18, 2014 (TW) 103144284

(51) Int. Cl. H05K 1/03; B32B 17/06; H05K 1/05; C08G 59/62; C08G 59/42; C08L 71/12; B32B 15/20; C08L 63/00

(52) U.S. Cl. CPC H05K 1/0373; B32B 15/20; B32B 17/061; C08L 63/00; C08G 59/621; C08G 59/4284; C08L 71/12; H05K 1/056; H05K 1/0393; B32B 2260/021; B32B 2260/046; B32B 2305/076; B32B 2307/204; B32B 2457/08; C08L 2203/20; H05K 2201/0275

(57) ABSTRACT

A prepreg is provided. The prepreg is prepared by immersing a reinforcing material into a resin composition and drying the immersed reinforcing material, wherein the resin composition has a first dielectric constant and comprises a thermosetting resin component, a hardener and a filler. The reinforcing material has a second dielectric constant, and the ratio of the first dielectric constant to the second dielectric constant ranges from 0.8 to 1.05.

### CLAIM FOR PRIORITY

This application claims the benefit of U.S. Provisional Patent Application No. 61/921,113, filed on Dec. 27, 2013. This application also claims priority to Taiwan patent application No. 103144284, filed Dec. 18, 2014. The contents of these priority applications are incorporated herein by reference.

### CROSS-REFERENCES TO RELATED APPLICATIONS

Not applicable.

### BACKGROUND OF THE INVENTION

1. Field of the Invention

The present invention provides a prepreg and a laminate prepared using the same. Specifically, the present invention provides a prepreg useful for preparing a laminate with a uniform dielectric constant (Dk).

2. Descriptions of the Related Art

Printed circuit boards (PCBs) are circuit substrates that are used for electronic devices to load other electronic components and to electrically connect the components to provide a stable circuit working environment. One kind of conventional printed circuit board is a copper clad laminate (CCL), which is primarily composed of resin(s), reinforcing material(s) and copper foil(s). Conventional resins include epoxy resins, phenolic resins, polyamine formaldehyde resins, silicone resins or polytetrafluoroethylene resins. Conventional reinforcing materials include glass fiber cloths, glass fiber mats, insulating papers or linen cloths.

In general, a print circuit board can be prepared by using the following method: immersing a reinforcing material, such as glass fiber fabric into a resin (e.g. epoxy resin), and curing the immersed glass fiber fabric into a semi-cured state to obtain a prepreg; superimposing certain layers of the prepregs and superimposing a metal foil on at least one external surface of the superimposed prepreg to provide a superimposed object; hot-pressing the superimposed object to obtain a metal clad laminate; etching the metal foil on the surface of the metal clad laminate to form a defined circuit pattern; and finally, drilling a plurality of holes on the metal clad laminate and plating these holes with a conductive material to form via holes to accomplish the preparation of the printed circuit board.

The efficiency and throughput of integrated circuit (IC) are continuously upgraded with the modification of the manufacturing technology of IC. To fully release the capability of the high performance ICs installed on the PCB, signals must be transmitted between these ICs at a high speed and high throughput. In other words, the electronic properties of the signal traces on the PCB should be good enough to keep up with the development of high performance ICs to realize a high data transmission rate.

However, the most common problem is that when a set of signals are transmitted through parallel traces, the signals will become nonsynchronous because of a signal delay or signal offset, which is called “signal skew”. Specifically, when a pair of synchronous signals are transmitted between two ICs through a pair of signal traces on the PCB, the transmission of signals will be affected by the physical property of the signal traces. Therefore, if the physical property of the signal traces are different from each other, the required transmission time of the signals will be different. This will result in a delay gap between a pair of synchronous signals after being transmitted through different signal traces, which will affect the operation of the receiving IC.

The difference between the physical properties of the signal traces is due to the surrounding PCB materials. Specifically, a PCB is consisted of a “resin composition” and a “reinforcing material”, which are different materials and therefore have different dielectric constant values. Since the physical properties of the signal traces inevitably will be affected by the surrounding PCB materials, the signal traces close to the resin composition will be greatly influenced by the resin composition while the signal traces close to the reinforcing material will be greatly influenced by the reinforcing material. As the result, the physical properties of these signal traces become different, and the “signal skew” problem occurs.

For example, FIG. 1 is a cross sectional view of a known PCB including a pair of parallel signal traces 111 and 114. Numeral 106 represents the distance between the signal trace 111 and the nearest glass fiber 112 (reinforcing material), while numeral 108 represents the distance between the signal trace 114 and the nearest glass fiber 116 (reinforcing material). Since the distance 108 is shorter than the distance 106 (i.e. the distance between the signal trace 114 and the glass fiber 116 is shorter than that between the signal trace 111 and the glass fiber 112), the influence from the glass fibers is greater in the signal trace 114 than the signal trace 111. This makes the dielectric properties of signal traces 11 and 114 become different and thus, causes the “signal skew” problem. To solve the “signal skew” problem, prior arts have all tried to change the design of the circuit to make the conditions of the position of each signal traces as equal as possible. However, the change of circuit has its limit in practice and is costly.

In view of this, the present invention provides a prepreg, which is useful in preparing a laminate with a uniform dielectric property and therefore is effective in solving the problem of “signal skew” in the PCB application without the need of changing the signal trace design.

### SUMMARY OF THE INVENTION

One objective of the present invention is to provide a prepreg, prepared by immersing a reinforcing material into a resin composition and drying the immersed reinforcing material, wherein the resin composition has a first dielectric constant and comprises a thermosetting resin component, a hardener and a filler. The reinforcing material has a second dielectric constant and the ratio of the first dielectric constant to the second dielectric constant ranges from 0.8 to 1.05.

Another objective of the present invention is to provide a laminate, comprising a synthetic layer and a metal layer, wherein the synthetic layer is made from the prepreg as mentioned above.

To render the above objectives, technical features and advantages of the present invention more apparent, the present invention will be described in detail with reference to some embodiments hereinafter.

### BRIEF DESCRIPTION OF THE DRAWINGS

FIG. 1 is a cross sectional view of a known PCB.

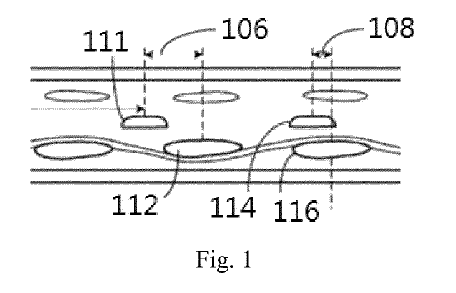

FIG. 2 shows a chart showing the result of the phase angle offset test of the examples and comparative examples.

### DESCRIPTION OF THE PREFERRED EMBODIMENT

Hereinafter, some embodiments in accordance with the present invention will be described in detail. However, without departing from the spirit of the present invention, the present invention may be applied to various embodiments. The scope of the present invention shall not be considered to be limited to what is illustrated herein. Furthermore, unless it is additionally explained, the expressions “a”, “the”, or the like recited in the specification of the present invention (especially in the claims) should include both the singular and plural forms. Unless it is additionally explained, when describing the components in the solution, mixture, and composition in the specification, the amount of each constituent is counted based on the solid content, i.e., disregarding the weight of the solvent.

The prepreg of the present invention features in being prepared by a resin composition with a first dielectric constant and a reinforcing material with a second dielectric constant. The ratio of the first dielectric constant to the second dielectric constant ranges from 0.8 to 1.05. The laminate prepared from the prepreg of the present invention has a uniform dielectric property and therefore is useful in PCB application. The influence from the board material to the signal traces at any position of the PCB will be roughly the same, and as a result, the uniformity of the signal transmitting rates among the signal traces will be improved significantly. Hence, the present invention eliminates the “signal skew” problem without changing the design of the circuit and therefore, has a wide range of adaptability.

Specifically, the prepreg of the present invention is provided by immersing a reinforcing material into a resin composition and drying the immersed reinforcing material, wherein the resin composition has a first dielectric constant and comprises a thermosetting resin component, a hardener and a filler. The reinforcing material has a second dielectric constant, and the ratio of the first dielectric constant to the second dielectric constant ranges from 0.8 to 1.05, preferably from 0.9 to 1.05, and most preferably from 0.95 to 1. In principle, the closer the values of the first dielectric constant and the second dielectric constant, the more significant the efficacy in solving the signal skew.

According to the present invention, the values of the dielectric constant of the resin composition (the first dielectric constant) and the dielectric constant of the reinforcing material (the second dielectric constant) are not particularly limited; they can be chose depending on needs. Table 1 below illustrates the dielectric constants (Dk) and the dissipation factors (Df) of several common thermosetting resins, hardeners, fillers and reinforcing materials. In one embodiment of the present invention, one may select a desired reinforcing material first and determine the dielectric constant of the selected reinforcing material, and accordingly select suitable thermosetting resin, hardener and filler each in their proper amount such that the ratio of the first dielectric constant to the second dielectric constant meets the specified range (from 0.8 to 1.05). For example, in the case of preparing a laminate with a high dielectric constant, one may select a reinforcing material with a high dielectric constant, such as an E-class glass, and formulate a resin composition while adjusting the dielectric constant of the resin composition (the first dielectric constant) to be identical or close to the dielectric constant of the reinforcing material (the second dielectric constant). The formulation could be done by for example adding a filler with a dielectric constant into a thermosetting resin with a low dielectric constant with a proper hardener to increase the overall dielectric constant value of the resin composition. On the contrary, one may select a reinforcing material with a low dielectric constant to prepare a laminate with a low dielectric constant. In some embodiments of the present invention, a filler with a high dielectric constant is added into the formulation of the thermosetting resin component and hardener with low dielectric constants to raise the dielectric constant of the whole resin composition to thereby obtain a laminate with a high dielectric constant.

TABLE 1

| | Dk | Df |
|---|---|---|
| Thermosetting resin | | |
| polytetrafluoroethylene (PTFE) | 2.1 | 0.001 |
| polyphenylene ether (PPE) | 2.4 | 0.005 |
| polystyrene (PS) | 2.5 | 0.003 |
| modified PPE (mPPE) | 2.5 | 0.005 |
| polysulfone (PSF) | 3 | 0.01 |
| polyethersulfone (PES) | 3.2 | 0.01 |
| polyphenylene sulfide (PPS) | 3.2 | 0.009 |
| polyethylene terephthalate (PET) | 3.3 | 0.008 |
| polyetherimide (PEI) | 3.5 | 0.02 |
| polyimide (PI) | 3.5 | 0.01 |
| epoxy | 4 | 0.02 |
| Hardener | | |
| phenolic novolac (PN) | 4.5 | 0.04 |
| styrene maleic anhydride copolymer (SMA) | 2.5 | 0.007 |
| cyanate ester (CE) | 2.7 | 0.007 |
| bismaleimide (BMI) | 3.5 | 0.01 |
| Filler | | |
| SrTiO₃ | 70 | 0.015 |
| quartz with surface modification | 3.8 | 0.002 |
| aluminium hydroxide (ATH) | 7.0 | — |
| quartz | 4.5 | 0.0015 |
| talc powder | 7.5 | — |
| Reinforcing material | | |
| E-class glass | 6.2 | 0.002 |
| S-class glass | 5.2 | 0.003 |
| NE-class glass | 4.6 | 0.0007 |
| D-class glass | 4.0 | 0.0026 |
| quartz | 3.7 | 0.0001 |
| high-modulus polypropylene (HMPP) | 2.3 | 0.0002 |
| aramid | 4.5 | 0.019 |
| ultra-high molecular weight polyethylene | 2.3 | 0.0005 |
| (UHMWPE) | | |

According to the present invention, the material and structure of the reinforcing material are not particularly limited. The reinforcing material could be any known reinforcing material. For example, the reinforcing material may be paper, cloth or felt composed of a fiber selected from the group consisting of paper fiber, glass fiber, quartz fiber, organic polymer fiber, carbon fiber, and combinations thereof. Examples of said organic polymer fiber include high-modulus polypropylene (HMPP) fiber, polyamide fiber, ultra-high molecular weight polyethylene (UHMWPE) fiber, and any combinations thereof. In some embodiments of the present invention, the reinforcing material is composed of E-class glass fiber or NE-class glass fiber.

“Thermosetting resin” refers to a polymer that can be gradually cured by forming a network structure through a heat treatment. According to the present invention, the thermosetting resin component of the resin composition can be provided by a single thermosetting resin or a mixture of multiple thermosetting resins. For example, the thermosetting resin component of the resin composition may be selected from the group consisting of epoxy resin, benzoxazine resin, polyphenylene ether resin, and combinations thereof. In some embodiments of the present invention, the thermosetting resin component is epoxy resin or polyphenylene ether resin.

The hardener in the resin composition can promote or regulate the intermolecular bridging effect of the resin composition to thereby obtain a network structure. The type of hardener is not particularly limited; it can be any hardener which can provide the desired hardening effect. For example, but not limited thereto, the hardener in the resin composition can be a conventional hardener selected from a group consisting of phenolic novolac (PN), styrene maleic anhydride copolymer (SMA), cyanate ester (CE), bismaleimide (BMI), 4,4′-diaminodiphenyl sulfone (DDS), benzoxazine and its ring-opening polymer, triazine, dicyandiamide (Dicy), and combinations thereof. In some embodiments of the present invention, PN, SMA, CE, and/or BMI are illustrated as hardeners.

The filler in the resin composition can adjust not only the physicochemical properties but also the dielectric constant of the resin composition. Any filler may be used to modify the physicochemical properties of the resin composition as long as the required ratio of dielectric constant (from 0.8 to 1.05) is met. In some embodiments of the present invention, a filler powder with a high dielectric constant is used to prepare a laminate with a high dielectric constant. The filler with a high dielectric constant may be a ceramic powder with a high dielectric constant, such as a ceramic powder with perovskite or sudo-perovskite lattice structure. Examples of the ceramic powder with perovskite or sudo-perovskite lattice structure include, but is not limited to, TiO₂, SrTiO₃, CaTiO₃, BaTiO₃, MgTiO₃, a sintered material of two or more of the foregoing compounds, and combinations thereof. Examples of the sintered material of two or more of the foregoing compound includes SrCaTiO₃, SrBaTiO₃, etc. In addition, the ceramic powders may be further doped with Si, Co, Ni, Mn, and/or rare earth elements. NPO is one of the examples known in the art. Among the above ceramic powders, titanium dioxide (TiO₂) is cheap and SrTiO₃ is most efficient for adjusting dielectric constant. In some embodiments of the present, SrTiO₃ is illustrated as a filler.

According to the present invention, the amounts of the thermosetting resin, the hardener, and filler of the resin composition are not particularly limited and may be adjusted depending on the needs of the user without affecting the hardening effect or running counter to the specified ratio conditions of the dielectric constants. In general, the amount of the hardener is 30 parts by weight to 70 parts by weight per 100 parts by weight of the thermosetting resin component, and the amount of the filler is 30 parts by weight to 180 parts by weight per 100 parts by weight of the thermosetting resin component. In the following examples, the thermosetting resin component may be epoxy resin. In the case where the reinforcing material is composed of E-class glass fiber, the amount of the filler is 80 parts by weight to 160 parts by weight per 100 parts by weight of the thermosetting resin component, and in the case where the reinforcing material is composed of NE-class glass fiber, the amount of the filler is 30 parts of weight to 100 parts by weight per 100 parts by weight of the thermosetting resin component. Alternatively, the thermosetting resin component may be polyphenylene ether. In the case where the reinforcing material is composed of E-class glass fiber, the amount of the filler is 100 parts by weight to 180 parts by weight per 100 parts by weight of the thermosetting resin component. In the case where the reinforcing material is composed of NE-class glass fiber, the amount of the filler is 50 parts of weight to 120 parts by weight per 100 parts by weight of the thermosetting resin component.

Depending on the users' needs, the resin composition may further comprise other additives. The examples of the additives include a hardening promoter, a dispersing agent, a flexibilizer, a flame retardant, a release agent, a silane coupling reagent, and combinations thereof, but is not limited thereto. For example, a hardening promoter selected form the following group may be added to improve the hardening effect: benzoyl peroxide (BPO), imidazole (MI), 2-methylimidazole (2MI), 2-ethyl-4-methylimidazole (2E4MI), 2-phenylimidazole (2PI), and combinations thereof. As for the amount of the additives, it can be easily adjusted by persons with ordinary skill in the art depending on the needs based on the disclosure of the specification and is not particularly limited.

The prepreg of the present invention may be prepared by the following method: evenly mixing the thermosetting resin component, hardener and filler of the resin composition through a stirrer and dissolving or dispersing the obtained mixture into a solvent to obtain a vanish of the resin composition; coating a reinforcing material with the resin composition; and then drying the coated reinforcing material (B-stage) to obtain the prepreg. Drying conditions are not particularly limited and can be adjusted depending on the needs by persons with ordinary skill in the art based on the disclosure of the specification. In some embodiments of the present invention, the reinforcing material coated with the resin composition is heated and dried at 175° C. for 2 to 15 minutes. The solvent may be any inert solvent which can dissolve or disperse but not react with the components of the resin composition. For example, the solvent which can dissolve or disperse the resin composition of the present invention includes, but is not limited to, methyl ethyl ketone (MEK), cyclohexanone, N,N-dimethyl formamide (DMF), propylene glycol monomethyl ether (PM), propylene glycol monomethyl ether acetate (PMA), acetone, toluene, γ-butyrolactone, butanone, xylene, methyl isobutyl ketone, N,N-dimethyl acetamide (DMAc), N-methyl-pyrolidone (NMP), and mixtures thereof. The amount of the solvent is not particularly limited as long as the components of the resin composition can be mixed evenly. In some embodiments of the present invention, a mixture of MEK and cyclohexanone is used as the solvent in an amount ranging from 40 parts by weight to 160 parts by weight per 100 parts by weight of the thermosetting resin.

The prepreg of the present invention can be used for manufacturing a laminate. Hence, the present invention further provides a laminate comprising a synthetic layer and a metal layer, wherein the synthetic layer is made from the above prepreg. The laminate may be prepared by the following process: superimposing a plurality of prepregs and superimposing a metal foil (such as a copper foil) on at least one external surface of the superimposed prepregs to provide a superimposed object; and performing a hot-pressing operation onto the superimposed object to obtain the laminate. In addition, a printed circuit board can be obtained by patterning the metal foil of the laminate.

The present invention will be further illustrated by the embodiments hereinafter, wherein, the measuring instruments and methods are respectively as follows:

[Dielectric Constant Measurement]

Dielectric constant (Dk) is measured according to ASTM D150 under an operating frequency of 1 GHz.

[Time Delay and Standard Deviation of Time Delay Measurement]

A reference point is measured by connecting the two connecting ends of the time domain reflectometer. The two connecting ends of the time domain reflectometer are then connected to one of the signal traces to be tested to measure the delay time of the signal compared to the reference point (i.e. “time delay”). The standard deviation among the delay time of every signal traces is then mathematically calculated (i.e. “time delay Stddev”).

[Phase Angle Offset Measurement]

Phase angle offset is measured by measuring the S parameter of differential coil with a 4 ports network analyzer and then calculating the difference between the phase angles S21 and S43.

### Preparation of the Prepreg

### Example 1

According to the ratio shown in Table 2, epoxy resin (EPON-1134, Momentive Co.) as the thermosetting resin component, phenolic novolac (CCP8110, Eternal Materials Co.) as the hardener, strontium titanate (SrTiO₃) (Superrite Co.) as the filler, 2-ethyl-4-methylimidazole (2E4MI) (Shikoku Co.) as the hardening promoter, and a dispersing agent (Z-6040, Dow Corning Co.) were mixed under room temperature with a stirrer for 60 minutes, followed by adding methyl ethyl ketone (MEK) (Transchief Co.) and cyclohexanone (Hsin Chong Co.) thereinto. After stirring under room temperature for 120 minutes, a resin composition 1 was obtained. The dielectric constant of the resin composition 1 was measured and is recorded in Table 2.

An E-class glass fiber cloth (hereinafter “E-glass”) (UNITIKA Co.) was used as the reinforcing material. The dielectric constant of the E-glass reinforcing material (second dielectric constant) was measured, the ratio of the first dielectric constant to the second dielectric constant was calculated, and the results are recorded in Table 2.

Then, the resin composition 1 was coated on the E-glass reinforcing material by a roller. The coated E-glass reinforcing material was then placed into an oven and dried at 175° C. for 2 to 15 minutes to produce a prepreg 1 in a semi-cured state.

### Example 2

The preparation procedures of Example 1 were repeated to prepare a resin composition 2 and the resin composition 2 was then used to prepare a prepreg 2, except that styrene maleic anhydride copolymer (SMA) (EF-40, Sartomer Co.) and cyanate ester (CE) (BA-230S, Lonza) were used as the hardener, a flexibilizer (EPON 58006, Momentive Co.) was additionally added, and the amounts of each component were adjusted as shown in Table 2.

### Example 3

The preparation procedures of Example 2 were repeated to prepare a resin composition 3 and the resin composition 3 was then used to prepare a prepreg 3, except that polyphenylene ether (SA-90, Sabic Co.) was used as the thermosetting resin component, maleinimide resin (BMI-70, Otsuka Co.) was used as the hardener, and the amounts of each component were adjusted as shown in Table 2.

### Example 4

The preparation procedures of Example 1 were repeated to prepare a resin composition 4 and the resin composition 4 was then used to prepare a prepreg 4, except that a NE-class glass fiber cloth (Nittobo Co.; hereinafter “NE-glass”) was used as the reinforcing material, and the amounts of each component were adjusted as shown in Table 2.

### Example 5

The preparation procedures of Example 2 were repeated to prepare a resin composition 5 and the resin composition 5 was then used to prepare a prepreg 5, except that the NE-glass was used as the reinforcing material, and the amounts of each component were adjusted as shown in Table 2.

### Example 6

The preparation procedures of Example 5 were repeated to prepare a resin composition 6 and the resin composition 6 was then used to prepare a prepreg 6, except that the amounts of each component were adjusted as shown in Table 2.

### Example 7

The preparation procedures of Example 3 were repeated to prepare a resin composition 7 and the resin composition 7 was then used to prepare a prepreg 7, except that the NE-glass was used as the reinforcing material, and the amounts of each component were adjusted as shown in Table 2.

### Comparative Example 1

The preparation procedures of Example 1 were repeated to prepare a comparative resin composition 1 and the comparative resin composition 1 was then used to prepare a comparative prepreg 1, except that the amounts of each component were adjusted to make the ratio of the first dielectric constant to the second dielectric constant outside the specified range of the present invention, as shown in Table 2.

### Comparative Example 2

The preparation procedures of Comparative Example 1 were repeated to prepare a comparative resin composition 2 and the comparative resin composition 2 was then used to prepare a comparative prepreg 2, except that the NE-glass was used as the reinforcing material, and the amounts of each component were adjusted as shown in Table 2.

### Comparative Example 3

The preparation procedures of Example 7 were repeated to prepare a comparative resin composition 3 and the comparative resin composition 3 was then used to prepare a comparative prepreg 3, except that the amounts of each component were adjusted to make the ratio of the first dielectric constant to the second dielectric constant outside the specified range of the present invention, as shown in Table 2.

TABLE 2

| | | | | | | | | | Compar- | Compar- | Compar- |
|---|---|---|---|---|---|---|---|---|---|---|---|
| | | Exam- | Exam- | Exam- | Exam- | Exam- | Exam- | Exam- | ative | ative | ative |
| | | ple 1 | ple 2 | ple 3 | ple 4 | ple 5 | ple 6 | ple 7 | Example 1 | Example 2 | Example 3 |
| thermosetting | epoxy resin | 100 | 100 | 0 | 100 | 100 | 100 | 0 | 100 | 100 | 0 |
| resin | polyphenylene | 0 | 0 | 100 | 0 | 0 | 0 | 100 | 0 | 0 | 100 |
| component | ether | | | | | | | | | | |
| hardener | PN | 35 | 0 | 0 | 35 | 0 | 0 | 0 | 35 | 35 | 0 |
| | SMA | 0 | 30 | 0 | 0 | 30 | 30 | 0 | 0 | 0 | 0 |
| | CE | 0 | 30 | 0 | 0 | 30 | 30 | 0 | 0 | 0 | 0 |
| | BMI | 0 | 0 | 50 | 0 | 0 | 0 | 50 | 0 | 0 | 50 |
| filler | SrTiO₃ | 100 | 140 | 160 | 40 | 60 | 80 | 60 | 40 | 80 | 20 |
| hardening | 2E4MI | 0.3 | 0.2 | 0.1 | 0.2 | 0.1 | 0.15 | 0.1 | 0.1 | 0.2 | 0.1 |
| promoter | | | | | | | | | | | |
| additives | flexibilizer | 0 | 10 | 20 | 0 | 10 | 10 | 20 | 0 | 0 | 20 |
| | dispersing | 10 | 14 | 15 | 4 | 6 | 8 | 6 | 0 | 0 | 2 |
| | agent | | | | | | | | | | |
| solvent | MEK | 50 | 60 | 80 | 20 | 30 | 40 | 30 | 20 | 40 | 10 |
| | cyclohexanone | 50 | 60 | 80 | 20 | 30 | 40 | 30 | 20 | 40 | 10 |

| | | | | | | | | | | |
|---|---|---|---|---|---|---|---|---|---|---|
| reinforcing material | E-glass | E-glass | E-glass | NE-glass | NE-glass | NE-glass | NE-glass | E-glass | NE-glass | NE-glass |
| first dielectric constant | 6.5 | 6.26 | 6.2 | 4.4 | 4.18 | 4.4 | 4.4 | 3.84 | 5.58 | 3.6 |
| second dielectric constant | 6.2 | 6.2 | 6.2 | 4.6 | 4.6 | 4.6 | 4.6 | 6.2 | 4.6 | 4.6 |
| ratio of first dielectric constant | 1.04 | 1.01 | 1.00 | 0.95 | 0.91 | 0.96 | 0.96 | 0.62 | 1.21 | 0.78 |
| to second dielectric constant | | | | | | | | | | |

[Preparation of the Laminate]

The laminates were prepared using prepregs 1 to 7 and comparative prepregs 1 to 3, respectively. In detail, four pieces of prepregs were superimposed and two sheets of copper foil (0.5 oz.) were respectively superimposed on the two external surfaces of the superimposed prepregs to provide a superimposed object. A hot-pressing operation was performed on each of the prepared objects to provide laminates 1 to 7 (corresponding to prepregs 1 to 7) and comparative laminates 1 to 3 (corresponding to comparative prepregs 1 to 3). Herein, the hot-pressing conditions were as follows: raising the temperature to 200° C. to 220° C. with a heating rate of 1.0 to 3.0° C./min, and hot-pressing for 180 minutes under the full pressure of 15 kg/cm² (initial pressure was 8 kg/cm²) at said temperature.

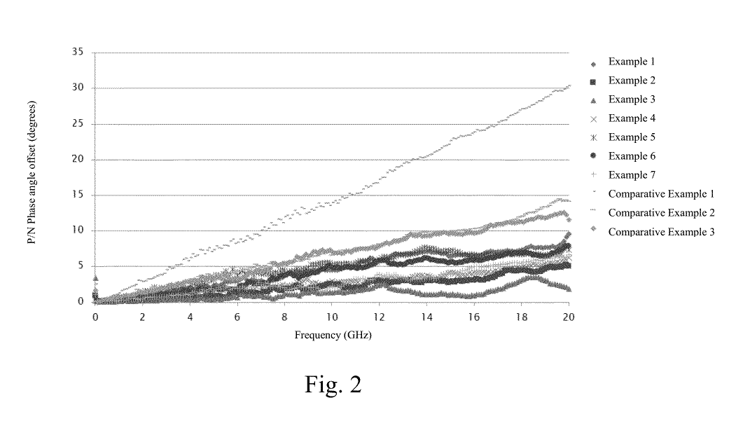

The time delay, standard deviation of time delay, and phase angle offset of laminates 1 to 7 and comparative laminates 1 to 3 were measured. The results were tabulated in Table 3 and are shown in FIG. 2.

TABLE 3

| | | | | | | | | Compar- | Compar- | Compar- |
|---|---|---|---|---|---|---|---|---|---|---|
| | Exam- | Exam- | Exam- | Exam- | Exam- | Exam- | Exam- | ative | ative | ative |
| | ple 1 | ple 2 | ple 3 | ple 4 | ple 5 | ple 6 | ple 7 | Example 1 | Example 2 | Example 3 |
| first dielectric | 6.5 | 6.26 | 6.2 | 4.4 | 4.18 | 4.4 | 4.4 | 3.84 | 5.58 | 3.6 |
| constant (resin | | | | | | | | | | |
| composition) | | | | | | | | | | |
| second dielectric | 6.2 | 6.2 | 6.2 | 4.6 | 4.6 | 4.6 | 4.6 | 6.2 | 4.6 | 4.6 |
| constant | | | | | | | | | | |
| (reinforcing material) | | | | | | | | | | |
| ratio of first | 1.04 | 1.01 | 1.00 | 0.95 | 0.91 | 0.96 | 0.96 | 0.62 | 1.21 | 0.78 |
| dielectric constant | | | | | | | | | | |
| to second | | | | | | | | | | |
| dielectric cosntant | | | | | | | | | | |
| time delay | 1486.8008 | 1466.6652 | 1461.7193 | 1259.6672 | 1242.7370 | 1255.7533 | 1259.8828 | 1268.8941 | 1365.8070 | 1182.7911 |
| (picosecond, ps) | | | | | | | | | | |
| standard deviation | 8.3298 | 1.6050 | 0.5503 | 4.6497 | 8.7942 | 5.4433 | 6.6677 | 34.2378 | 19.6244 | 17.8583 |
| of time delay | | | | | | | | | | |
| (picosecond, ps) | | | | | | | | | | |

As shown in Table 3 and FIG. 2, each of the laminates 1 to 7 prepared by the prepregs of the present invention has a uniform dielectric constant and a time delay and phase angle offset that are much smaller than that of the comparative laminates. Hence, the present invention effectively eliminates the “signal skew” problem.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A prepreg, prepared by immersing a reinforcing material into a resin composition and drying the immersed reinforcing material, wherein
the resin composition has a first dielectric constant and comprises a thermosetting resin component, a hardener and a filler,
the reinforcing material has a second dielectric constant, and
the ratio of the first dielectric constant to the second dielectric constant is from 0.8 to 1.05.

2. The prepreg of claim 1, wherein the ratio of the first dielectric constant to the second dielectric constant is from 0.9 to 1.05.

3. The prepreg of claim 1, wherein the reinforcing material is composed of a fiber selected from the group consisting of paper fiber, glass fiber, quartz fiber, organic polymer fiber, carbon fiber, and combinations thereof.

4. The prepreg of claim 3, wherein the organic polymer fiber is selected from the group consisting of high-modulus polypropylene (HMPP) fiber, polyamide fiber, ultra-high molecular weight polyethylene (UHMWPE) fiber, and combinations thereof.

5. The prepreg of claim 3, wherein the reinforcing material is composed of E-class glass fiber, NE-class glass fiber, or a combination of E-class glass fiber and NE-class glass fiber.

6. The prepreg of claim 1, wherein the thermosetting resin component is selected from the group consisting of epoxy resin, benzoxazine resin, polyphenylene ether resin, and combinations thereof.

7. The prepreg of claim 6, wherein the thermosetting resin component is epoxy resin or polyphenylene ether resin.

8. The prepreg of claim 1, wherein the hardener is selected from the group consisting of phenolic novolac (PN), styrene maleic anhydride copolymer (SMA), cyanate ester (CE), bismaleimide (BMI), 4,4′-diaminodiphenyl sulfone (DDS), benzoxazine and its ring-opening polymer, triazine, dicyandiamide (Dicy), and combinations thereof.

9. The prepreg of claim 1, wherein the filler is selected from the group consisting of TiO₂, SrTiO₃, CaTiO₃, BaTiO₃, MgTiO₃, a sintered material of two or more of the foregoing compounds, and combinations thereof.

10. The prepreg of claim 1, wherein the amount of the hardener is 30 parts by weight to 70 parts by weight per 100 parts by weight of the thermosetting resin component, and the amount of the filler is 30 parts by weight to 180 parts by weight per 100 parts by weight of the thermosetting resin component.

11. The prepreg of claim 1, wherein the thermosetting resin component is epoxy resin; and in the case where the reinforcing material is composed of E-class glass fiber, the amount of the filler is 80 parts by weight to 160 parts by weight per 100 parts by weight of the thermosetting resin component, and in the case where the reinforcing material is composed of NE-class glass fiber, the amount of the filler is 30 parts of weight to 100 parts by weight per 100 parts by weight of the thermosetting resin component.

12. The prepreg of claim 1, wherein the thermosetting resin component is polyphenylene ether; and in the case where the reinforcing material is composed of E-class glass fiber, the amount of the filler is 100 parts by weight to 180 parts by weight per 100 parts by weight of the thermosetting resin component, and in the case where the reinforcing material is composed of NE-class glass fiber, the amount of the filler is 50 parts of weight to 120 parts by weight per 100 parts by weight of the thermosetting resin component.

13. The prepreg of claim 1, wherein the resin composition further comprises an additive selected from the group consisting of a hardening promoter, a dispersing agent, a flexibilizer, a flame retardant, a release agent, and combinations thereof.

14. The prepreg of claim 13, wherein the hardening promoter is selected form the group consisting of benzoyl peroxide (BPO), imidazole (MI), 2-methylimidazole (2MI), 2-ethyl-4-methylimidazole (2E4MI), 2-phenylimidazole (2PI), and combinations thereof.

15. A laminate, comprising a synthetic layer and a metal layer, wherein the synthetic layer is made from the prepreg of claim 1.
